(19) United States
(12) Patent Application Publication
(10) Pub. No.: US 2013/0313727 A1
(43) Pub. Date: Nov. 28, 2013

(54) MULTI-STACKED BBUL PACKAGE

(71) Applicants: Eng Huat Goh, Phoenix, AZ (US); Hoay Tien Teoh, Phoenix, AZ (US)

(72) Inventors: Eng Huat Goh, Phoenix, AZ (US); Hoay Tien Teoh, Phoenix, AZ (US)

(21) Appl. No.: 13/995,139

(22) PCT Filed: May 23, 2012
(86) PCT No.: PCT/US12/39062

§ 371 Date: Jun. 17, 2013

(51) Int. Cl. H01L 21/50; H01L 23/48

(52) U.S. Cl. CPC H01L 21/50; H01L 23/48
USPC 257/777; 438/109

(57) ABSTRACT

A method including forming a first portion of a build-up carrier on at least one first die, the at least one first die; coupling at least one second die to the first portion of the build-up carrier, the at least one second die separated from the first die by the at least one layer of conductive material disposed between layers of dielectric material; and after coupling the at least one second die to the first portion of the build-up carrier, forming a second portion of the build-up carrier on the at least one second die. An apparatus including a build-up carrier including including alternating layers of conductive material and dielectric material and at least two dice therein in different planes of the build-up carrier.

### BACKGROUND

1. Field

Packaging for microelectronic devices.

2. Description of Related Art

Microelectronic packaging technology, including methods to mechanically and electrically attach a silicon die (e.g., a microprocessor) to a substrate or other carrier continues to be refined and improved. Bumpless Build-Up Layer (BBUL) technology is one approach to a packaging architecture. Among its advantages, BBUL eliminates the need for assembly, eliminates prior solder ball interconnections (e.g., flip-chip interconnections), reduces stress on low-k interlayer dielectric of dies due to die-to-substrate coefficient of thermal expansion (CTE mismatch), and reduces package inductance through elimination of core and flip-chip interconnect for improved input/output (I/O) and power delivery performance.

With shrinking electronic device sizes and increasing functionality, integrated circuit packages will need to occupy less space. One way to conserve space is to combine a device or package on top of a package. Current ways of integrating second devices (e.g., secondary dice) vertically to, for example, a system on chip (SOC) package is either package on package (POP) or through silicon via (TSV) integration. Both of these integration techniques require additional processing to attach the secondary die/module on top of the SOC package. The additional processing eventually creates assembly challenges. For example, in the case of a customer-owned POP (COPOP), the SOC package must be formed flat enough during the surface mount technology (SMT) reflow for the POP package to be properly soldered to the pad which drives process/material stackup characterization needed to achieve the desired outcome and also typically the size of the package is limited to small package sizes (e.g., a package size 8×8 square millimeter (mm²) to 12×12 mm²). While in the TSV scenario, it generally requires a thermal compression bonding (TCB) process which is not a very mature technology resulting in a slow throughput and assembly and reliability challenges.

### BRIEF DESCRIPTION OF THE DRAWINGS

FIG. 1 shows a cross-sectional view one embodiment of a portion of a microelectronic package including a primary die and two secondary dice in a build-up carrier.

FIG. 2 shows a cross-sectional exploded side view of a sacrificial substrate with sacrificial copper foils attached to opposite sides thereof.

FIG. 3 shows the structure of FIG. 2 following the introduction of secondary dice on a surface of a copper foil and a dielectric layer over the secondary dice in a process of forming a build-up carrier.

FIG. 4 shows the structure of FIG. 3 following the patterning of electrically conductive vias to contact points and a first electrically conductive layer or line on the dielectric layer.

FIG. 5 shows the structure of FIG. 4 following the introduction of a dielectric layer on the first conductive layer and electrically conductive vias to the first conductive layer and contact lands on the dielectric layer.

FIG. 6 shows the structure of FIG. 5 following the patterning of conductive lands on the dielectric layer.

FIG. 7 shows the structure of FIG. 6 following the attachment of a primary die on the dielectric layer.

FIG. 8 shows the structure of FIG. 7 following the introduction of a dielectric layer over the primary die.

FIG. 9 shows the structure of FIG. 8 following the formation of openings in the dielectric layer to contact points on the die and the contact lands.

FIG. 10 shows the structure of FIG. 9 following the introduction of an electrically conductive material in the vias and the patterning of an electrically conductive layer or line on the dielectric as well as the introduction of a dielectric layer on the electrically conductive layer and the formation of openings therein.

FIG. 11 shows the isolation of one package from the sacrificial substrate, the package including patterned contacts for a surface mount application.

FIG. 12 illustrates a schematic illustration of a computing device.

### DETAILED DESCRIPTION

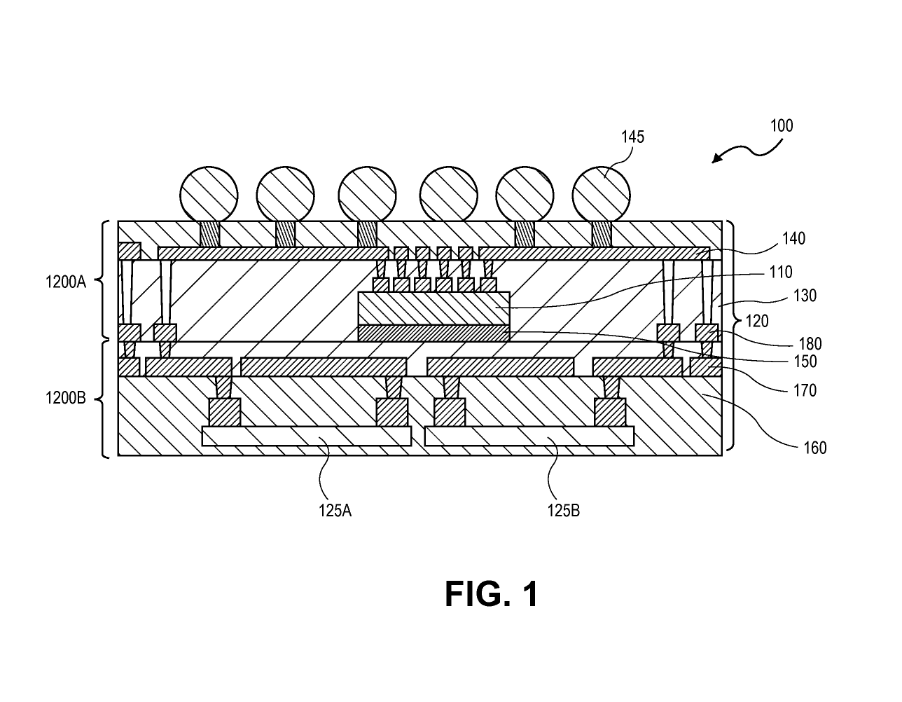

FIG. 1 shows a cross-sectional view of a microelectronic package according to one embodiment. As illustrated in FIG. 1, microelectronic package 100 utilizes bumpless build-up layer (BBUL) technology. Microelectronic package 100 includes carrier 120. For explanatory purposes, carrier 120 will be described with reference to two portions, portion 1200A and portion 1200B. It is appreciate that together portion 1200A and portion 1200B form a single integrated carrier.

Referring to FIG. 1, portion 1200A of carrier 120 includes primary die 110, such as a microprocessor die or a system on chip (SOC) die, embedded in portion 1200A device side up (as viewed). In one embodiment, die 110 is a silicon die or the like having a thickness of approximately 150 micrometers (μm). In another example, die 110 can be a silicon die or the like that has a thickness less than 150 μm such as 50 μm to 150 μm. It is appreciated that other thicknesses for die 110 are possible.

FIG. 1 shows that portion 1200A of carrier 120 includes multiple build-up layers including dielectric layers 130 of, for example, ABF and one or more electrically conductive layers or lines 140 (one shown) of, for example, copper or a copper alloy (connected with conductive vias or the like) that provide connectivity to die 110 (power, ground, input/output, etc.) through contacts 145 such as, for example, contacts suitable for a surface mount packaging implementation (e.g., a ball grid array). Die 110 and portion 1200A of carrier 120 are in direct physical contact with each other (e.g., there are no solder bumps connecting die 110 to carrier 120). Die 110 is directly electronically connected to electrically conductive contacts or conductive vias of portion 1200A of carrier 120. As illustrated, at least one electrically conductive layer 140 is connected through electrically conductive vias to portion 1200B. In FIG. 1, one of dielectric layers 130 surrounds the lateral side walls of die 110.

Underlying a back side of die 110 of microelectronic package 100 in FIG. 1, as viewed, is adhesive layer 150 of, for example, a die backside film (DBF) polymer, epoxy based adhesive with or without fillers. Underlying adhesive layer 150 is portion 1200B of carrier 120. Portion 1200B includes additional build-up layers including dielectric layers 160 and one or more electrically conductive layers or lines 170. Dielectric layers 160 (e.g., two or more) may be of a material similar to a material for dielectric layers 130 (e.g., ABF) or a different material. Conductive layers 170 (one shown) are, for example, a copper or copper alloy material. In this embodiment, conductive layers 170 are connected with electrically conductive vias or the like to one or more conductive layers 140 of portion 1200A of carrier 120.

In the embodiment shown in FIG. 1, package 100 also includes two secondary dice, die 125A and die 125B embedded in portion 1200B of carrier 120. In one embodiment, secondary dice are dice having a desired electrical configuration that may or may not be electrically connected to die 110. In the embodiment, shown in FIG. 1, secondary die 125A and secondary die 125B are electrically connected to die 100 through routing layers in carrier 120. Examples of secondary dice include but are not limited to a digital logic device, such as a dynamic random access memory (DRAM) device, a static random access memory (SRAM) device, a flash memory device, a microprocessor device, a digital signal processor (DSP) device, a graphics processor device, a crypto processor device, and an application specific integrated circuit (ASIC) device. In this embodiment, die 125A and die 125B are positioned device side up (as viewed). Die 125A and die 125B each contain electrical contact points (contacts) on a device side which are connected through electrically conductive vias to conductive layer 170.

FIG. 1 also shows contact lands 180 in portion 1200B or carrier 120 at the interface of first portion 1200A and second portion 1200B. Contact lands 180 are connected to electrically conductive layers of carrier 120, e.g., conductive layers of portion 1200A of carrier 120 through electrically conductive vias. Contact lands 180 in connection with electrically conductive layer 170, in this embodiment, provide a redistribution layer and together with electrically conductive vias to electrically conductive layer 140 an electrical connection between die 110 and dice 125A and 125B. Contact lands 180 may also allow additional interconnect points for the package (e.g., power, ground, input/output) between contacts 145 and secondary die 125A and/or secondary die 125B.

FIG. 1 shows primary die 110 in portion 1200A of carrier 120 and secondary dice 125A and 125B in portion 1200B. In another embodiment, such positions are reversed. FIG. 1 also shows two secondary dice. In another embodiment, a microelectronic package includes one secondary die. In a further embodiment, a microelectronic package includes more than two secondary dice. In a still further embodiment, a microelectronic package includes more than one primary die.

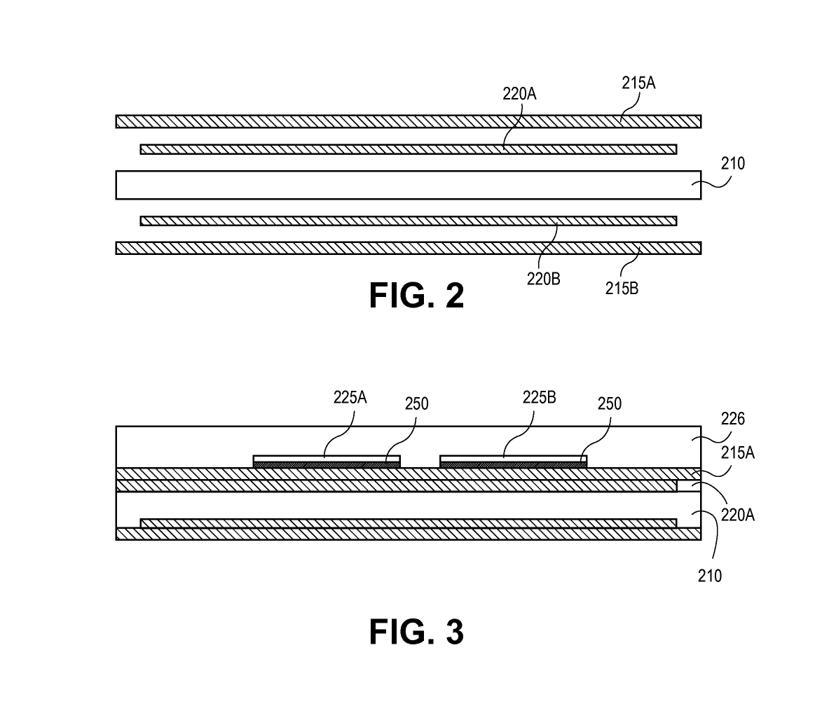

FIGS. 2-9 describe one embodiment for forming a microelectronic package, such as microelectronic package 100 (FIG. 1). Referring to FIG. 2, FIG. 2 shows an exploded cross-sectional side view of a portion of sacrificial substrate 210 of, for example, a prepeg material including opposing layers of copper foils 215A and 215B that are separated from sacrificial substrate 310 by shorter copper foil layers 220A and 220B, respectively. Copper foils 215A and 215B tend to stick to the shorter foils based on vacuum. One technique of forming build-up packages is to form two separate packages on a sacrificial substrate, one on a top surface sacrificial substrate 210 and one on a bottom surface (as viewed) and at some point during the formation process, each are separated from the sacrificial substrate. In the following description, a formation process will only be described and illustrated for a microelectronic package on the top surface. It is appreciated that a similar formation process may be followed on the bottom surface simultaneously.

FIG. 3 shows the structure of FIG. 2 following the introduction of secondary die 225A and secondary die 225B which are similar to secondary die 125A and secondary die 125B in FIG. 1. Secondary die 125A and secondary die 125B are attached to copper foil 215A device side up by, for example, adhesive 250 of, for example, DBF. In addition to secondary die 225A and secondary die 225B on copper foil 215A, contacts may optionally be introduced on copper foil 215A that might be used to electrical connect the ultimately formed package to an external device or devices suitable contacts include two layer contacts of a gold-nickel alloy and a copper or copper alloy formed by deposition (plating, sputtering).

Following the attachment of secondary die 225A and secondary die 225B and optional contacts, dielectric layer 260 of, for example, an ABF material possibly including a filler is introduced. One method of introduction of an ABF material is as a film that is laid on the secondary dice, the optional contacts and copper foil 215A.

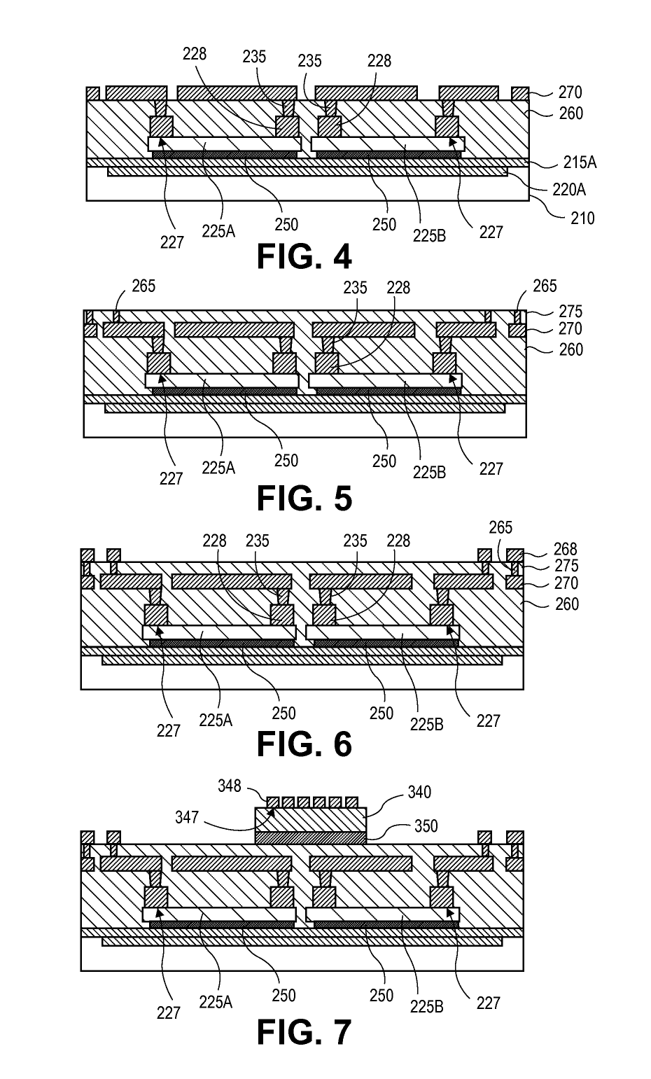

FIG. 4 shows the structure of FIG. 3 following the patterning of vias through dielectric layer 260 to contacts 227 on secondary die 225A and secondary die 225B and the formation of conductive vias and conductive layer 270 or line on each of dielectric layer 260. In one embodiment, die 225A and die 225B may include electrically conductive pillars 228 on contacts 227. Such pillars 228 may be added at the die fabrication stage. With regard to patterning vias in a material such as ABF, such patterning may be done by, for example, a drilling process. Once the vias are formed, electrical conductor (e.g., copper metal) patterning may be done in order to fill the vias and pattern electrically conductive layer or line 270 on dielectric layer 260, for example, using an electroless seed layer followed by a dry film resist (DFR) patterning and plating. The DFR may then be stripped followed by a flash etch to remove any unwanted electroless seed layer. It is appreciated that other methods are also suitable. FIG. 4 shows vias 235 filled with conductive material and represented as conductive vias including conductive vias to contacts 227 of respective secondary die 225A and secondary die 225B.

FIG. 5 shows the structure of FIG. 4 following the introduction of a dielectric layer. FIG. 5 shows dielectric layer 275 of, for example, an ABF material introduced as a film. FIG. 5 also shows the patterning of electrically conductive vias 265 formed through dielectric layer 275 to electrically conductive layer 270. A suitable material for electrically conductive vias 265 is copper deposited, for example, by an electroless process.

FIG. 6 shows the structure of FIG. 5 following the patterning of contact lands on conductive vias 265. Contact lands 268 are, for example, a copper or copper alloy deposited, for example, using an electroless seed layer followed by a DFR patterning and plating.

FIG. 7 shows the structure of FIG. 6 following the mounting of die 340 on dielectric layer 275 (on a top surface of dielectric layer 275 as viewed). In this embodiment, die 340 is connected by adhesive 350. A suitable adhesive material is DBF. In this embodiment, die 340 is positioned device side up (device side facing away from copper foil). Die 340 may include electrically conductive pillars 348 on contacts 347 (contact points). Such pillars 348 may be added at the die fabrication stage. In another embodiment, die 340 may have through substrate vias from a device side to a back side of the die. In such an embodiment, conductive vias 265 and optionally contact lands 268 could be patterned to conductive layer 270 in an area directly below die 340 to connect directly to the through substrate vias of die 340.

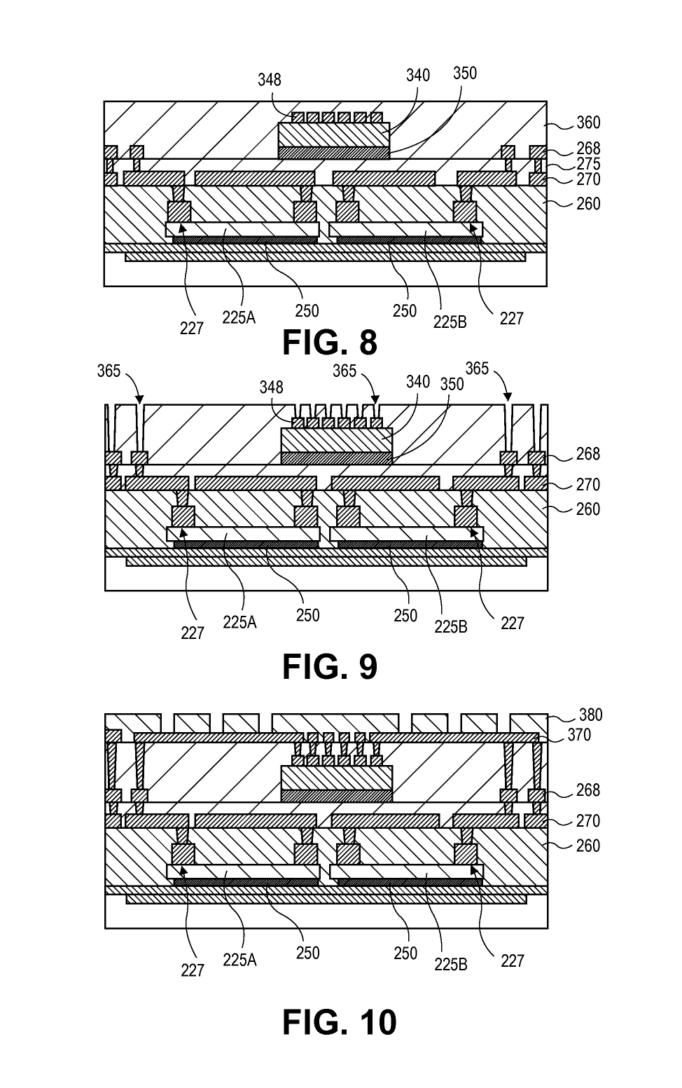

FIG. 8 shows the structure of FIG. 7 following the introduction of a dielectric layer. FIG. 8 shows dielectric layer 360 of, for example, an ABF material introduced as a film. Dielectric layer 360 encompasses or encapsulates die 340.

FIG. 9 shows the structure of FIG. 8 following the formation of openings 365 to contact lands 268 and to contact points on a device side of die 340 (openings to pillars 348). One way to form openings 365 through a dielectric material such as ABF is by a drilling process.

FIG. 10 shows the structure of FIG. 9 following the introduction of an electrical conductor (e.g., copper metal) in openings 365 and patterning of the conductor material into electrically conductive layer or line 370. One method includes using an electroless seed layer followed by a dry film resist (DFR) patterning and plating. The DFR may then be stripped followed by a flash etch to remove any unwanted electroless seed layer. It is appreciated that other methods are also suitable.

Once electrically conductive layer 370 is introduced and patterned, a dielectric layer is introduced on the structure. FIG. 10 shows the structure of FIG. 9 following the introduction of dielectric layer 380 on the structure and encapsulating electrically conductive layer 370. Patterning of additional levels of conductive lines (e.g., three additional levels separated from one another by dielectric layers (e.g., ABF film)) may follow. A typical BBUL package may have four to six levels of conductive lines or traces connected to one another or die 340 by conductive vias.

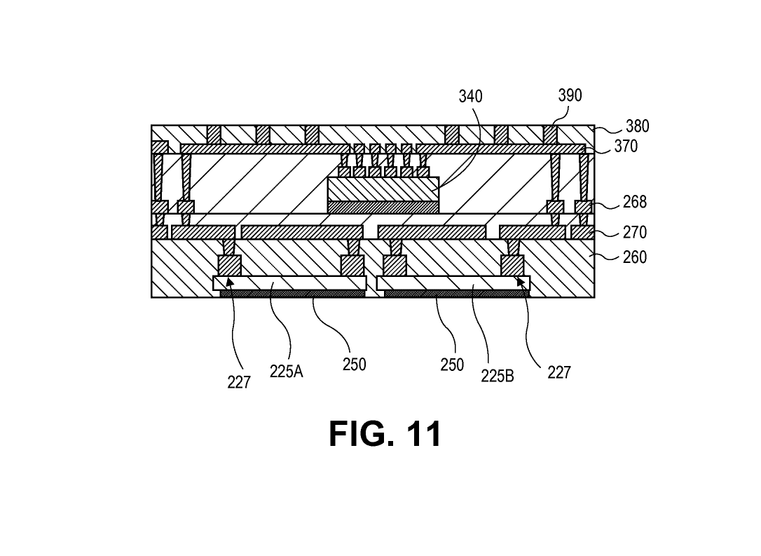

FIG. 11 shows the structure of FIG. 10 following the formation of openings through dielectric layer 380 to electrically conductive layer 370 and the introduction of an electrical conductor (e.g., copper metal) in the openings to form conductive vias 390 to which, for example, solder balls may be attached for a surface mount implementation. FIG. 11 also shows the structure following the separation of the structure from sacrificial substrate 210 and copper foil 215A. By removing the individual packages from sacrificial substrate 210 and copper foil 215A, FIG. 11 shows a free standing microelectronic package that has a primary die and secondary dice 225A and 225B therein.

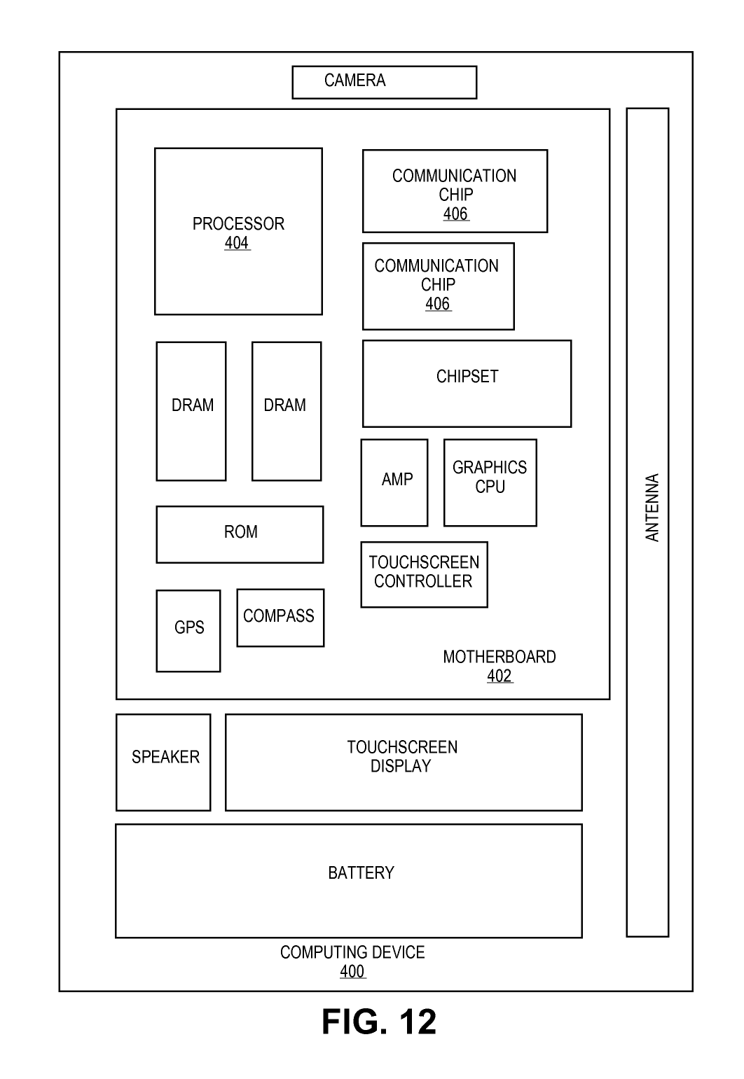

FIG. 12 illustrates a computing device 400 in accordance with one implementation. Computing device 400 houses board 402. Board 402 may include a number of components, including but not limited to processor 404 and at least one communication chip 406. Processor 404 is physically and electrically coupled to board 402. In some implementations the at least one communication chip 406 is also physically and electrically coupled to board 402. In further implementations, communication chip 406 is part of processor 404.

Depending on its applications, computing device 400 may include other components that may or may not be physically and electrically coupled to board 402. These other components include, but are not limited to, volatile memory (e.g., DRAM), non-volatile memory (e.g., ROM), flash memory, a graphics processor, a digital signal processor, a crypto processor, a chipset, an antenna, a display, a touchscreen display, a touchscreen controller, a battery, an audio codec, a video codec, a power amplifier, a global positioning system (GPS) device, a compass, an accelerometer, a gyroscope, a speaker, a camera, and a mass storage device (such as hard disk drive, compact disk (CD), digital versatile disk (DVD), and so forth).

Communication chip 406 enables wireless communications for the transfer of data to and from computing device 400. The term “wireless” and its derivatives may be used to describe circuits, devices, systems, methods, techniques, communications channels, etc., that may communicate data through the use of modulated electromagnetic radiation through a non-solid medium. The term does not imply that the associated devices do not contain any wires, although in some embodiments they might not. Communication chip 406 may implement any of a number of wireless standards or protocols, including but not limited to Wi-Fi (IEEE 802.11 family), WiMAX (IEEE 802.16 family), IEEE 802.20, long term evolution (LTE), Ev-DO, HSPA+, HSDPA+, HSUPA+, EDGE, GSM, GPRS, CDMA, TDMA, DECT, Bluetooth, derivatives thereof, as well as any other wireless protocols that are designated as 3G, 4G, 5G, and beyond. Computing device 400 may include a plurality of communication chips 406. For instance, a first communication chip 406 may be dedicated to shorter range wireless communications such as Wi-Fi and Bluetooth and a second communication chip 406 may be dedicated to longer range wireless communications such as GPS, EDGE, GPRS, CDMA, WiMAX, LTE, Ev-DO, and others.

Processor 404 of computing device 400 includes an integrated circuit die packaged within processor 404. In some implementations, the package formed in accordance with embodiment described above utilizes BBUL technology with a carrier includes a primary die (e.g., microprocessor or SOC die) and one or more secondary dice (e.g., memory die or dice). The term “processor” may refer to any device or portion of a device that processes electronic data from registers and/or memory to transform that electronic data into other electronic data that may be stored in registers and/or memory.

Communication chip 406 also includes an integrated circuit die packaged within communication chip 406. In accordance with another implementation, package is based on BBUL technology with a carrier includes a primary die (e.g., microprocessor or SOC die) and one or more secondary dice (e.g., memory die or dice). Such packaging will enable integration in a single package various devices, including but not limited to, a microprocessor chip (die) with a memory die with a graphics die with a chip set with GPS.

In further implementations, another component housed within computing device 400 may contain a microelectronic package based on BBUL technology with a carrier includes a primary die (e.g., microprocessor or SOC die) and one or more secondary dice (e.g., memory die or dice).

In various implementations, computing device 400 may be a laptop, a netbook, a notebook, an ultrabook, a smartphone, a tablet, a personal digital assistant (PDA), an ultra mobile PC, a mobile phone, a desktop computer, a server, a printer, a scanner, a monitor, a set-top box, an entertainment control unit, a digital camera, a portable music player, or a digital video recorder. In further implementations, computing device 400 may be any other electronic device that processes data.

In the description above, for the purposes of explanation, numerous specific details have been set forth in order to provide a thorough understanding of the embodiments. It will be apparent however, to one skilled in the art, that one or more other embodiments may be practiced without some of these specific details. The particular embodiments described are not provided to limit the invention but to illustrate it. The scope of the invention is not to be determined by the specific examples provided above but only by the claims below. In other instances, well-known structures, devices, and operations have been shown in block diagram form or without detail in order to avoid obscuring the understanding of the description. Where considered appropriate, reference numerals or terminal portions of reference numerals have been repeated among the figures to indicate corresponding or analogous elements, which may optionally have similar characteristics.

It should also be appreciated that reference throughout this specification to “one embodiment”, “an embodiment”, “one or more embodiments”, or “different embodiments”, for example, means that a particular feature may be included in the practice of the invention. Similarly, it should be appreciated that in the description various features are sometimes grouped together in a single embodiment, figure, or description thereof for the purpose of streamlining the disclosure and aiding in the understanding of various inventive aspects. This method of disclosure, however, is not to be interpreted as reflecting an intention that the invention requires more features than are expressly recited in each claim. Rather, as the following claims reflect, inventive aspects may lie in less than all features of a single disclosed embodiment. Thus, the claims following the Detailed Description are hereby expressly incorporated into this Detailed Description, with each claim standing on its own as a separate embodiment of the invention.

1. A method comprising:
forming a first portion of a build-up carrier on at least one first die, the at least one first die comprising a first side and an opposite second side comprising contact points, the first portion of the build-up carrier comprising at least one first layer of conductive material disposed between layers of dielectric material;
coupling at least one second die to the first portion of the build-up carrier; and
after coupling the at least one second die to the first portion of the build-up carrier, forming a second portion of the build-up carrier on the at least one second die, the second portion comprising at least one second layer of conductive material disposed between layers of dielectric material.

2. The method of claim 1, wherein the at least one first die is electrically coupled to the at least one second die through at least one of the at least one first layer of conductive material and the at least one second layer of conductive material.

3. The method of claim 1, wherein the at least one first die is electrically coupled to the at least one second die through each of the at least one first layer of conductive material and the at least one second layer of conductive material.

4. The method of claim 1, wherein the at least one first die is a secondary die and the at least one second die is a microprocessor.

5. The method of claim 1, wherein the at least one first die is a secondary die and the at least one second die is a system on chip die.

6. The method of claim 5, wherein the at least one first die is a memory die.

7. A method comprising:
forming a first portion of a build-up carrier on at least one first die, the first portion of the build-up carrier comprising at least one first layer of conductive material coupled to contact points of the at least one first die;
coupling at least one second die to the first portion of the build-up carrier; and
after coupling the at least one second die to the first portion of the build-up carrier, forming a second portion of the build-up carrier on the at least one second die, the second portion comprising at least one second layer of conductive material coupled to contact points of the at least one second die.

8. The method of claim 7, further comprising coupling the at least one first layer of conductive material to the at least one second layer of conductive material.

9. The method of claim 7, wherein the at least one first die is a secondary die and the at least one second die is a microprocessor.

10. The method of claim 7, wherein the at least one first die is a secondary die and the at least one second die is a system on chip die.

11. The method of claim 9, wherein the at least one first die is a memory die.

12. An apparatus comprising:
a build-up carrier comprising alternating layers of conductive material and dielectric material and at least two dice therein in different planes of the build-up carrier.

13. The apparatus of claim 12, wherein the at least two dice comprise a first die that is a microprocessor.

14. The apparatus of claim 13, wherein the at least two dice comprise a second die that is a secondary die.

15. The apparatus of claim 14, wherein the secondary die is a memory die.

16. The apparatus of claim 12, wherein the at least two dice are electrically coupled to one another through one or more conductive layers in the build-up carrier.
